(19) United States
(12) Patent Application Publication
(10) Pub. No.: US 2026/0333780 A1
(43) Pub. Date: Oct. 22, 2026

(54) Trench Junction Field Effect Transistor Including a Mesa Region

(71) Applicant: Infineon Technologies Austria AG, Villach (AT)

(72) Inventors: Hans Weber, Villach (AT); Andreas Riegler, Wernberg (AT); Michael Franz Treu, Villach (AT); Leo Aichriedler, Puch (AT)

(21) Appl. No.: 19/486,624

(22) PCT Filed: May 21, 2024
(86) PCT No.: PCT/EP2024/063961

§ 371 Date: Nov. 21, 2025

(30) Foreign Application Priority Data
May 22, 2023 (EP) 23174583

(51) Int. Cl. H10D 30/83; H10D 30/01; H10D 62/10; H10D 62/60; H10D 64/23; H10D 64/27

(52) U.S. Cl. CPC H10D 30/831; H10D 62/103; H10D 62/60; H10D 64/2527; H10D 64/513; H10D 64/518; H10D 30/051; H10D 62/124

(57) ABSTRACT

A trench junction field effect transistor, trench JFET (100), is proposed. The trench JFET (100) includes a mesa region (103) confined by first and second trenches (1061, 1062) spaced apart from each other in a first lateral direction (x1) of a semiconductor body (102), the first and second trenches (1061, 1062) extending from a first surface (108) into the semi-conductor body (102); a mesa channel region (104) of a first conductivity type (103); a first control region (1101) of a second conductivity type complementary to the first conductivity type arranged in the mesa region (103) adjacent to the first trench (1061); and a second control region (1102) of the second conductivity type arranged in the mesa region (103) adjacent to the second trench (1062). The mesa channel region (104) is arranged, in the first lateral direction (x1), between the first control region (1101) and the second control region (1102), and the first control region (1101) is electrically coupled to a source contact (S), and the second control region (1102) is electrically coupled to a gate contact (G).

### TECHNICAL FIELD

The present disclosure is related to a semiconductor device, in particular to a trench junction field effect transistor, trench JFET, including a mesa region.

### BACKGROUND

Technology development of new generations of semiconductor devices, e.g. junction field effect transistors (JFETs), aims at improving electric device characteristics and reducing costs by shrinking device geometries. Although costs may be reduced by shrinking device geometries, a variety of tradeoffs and challenges have to be met when increasing device functionalities per unit area. For example, a trade-off between area-specific on-state resistance, RₒₙxA, and reliability requirements influenced by, for example, switching efficiency, requires design optimization.

Thus, there is a need for an improved junction field effect transistor.

### SUMMARY

One example relates to a trench junction field effect transistor, JFET. The trench JFET includes a mesa region confined by first and second trenches spaced apart from each other in a first lateral direction of a semiconductor body, the first and second trenches extending from a first surface into the semiconductor body, a mesa channel region of a first conductivity type, a first control region of a second conductivity type complementary to the first conductivity type arranged in the mesa region adjacent to the first trench, and a second control region of the second conductivity type arranged in the mesa region adjacent to the second trench. The mesa channel region is arranged, in the first lateral direction, between the first control region and the second control region. The first control region is electrically coupled to a source contact, and the second control region is electrically coupled to a gate contact.

Another example relates to a trench junction field effect transistor, JFET. The trench JFET includes a mesa region confined by first and second trenches along a first lateral direction, the first and second trenches extending into a semiconductor body from a first surface of the semiconductor body, a mesa channel region of a first conductivity type, a first control region of a second conductivity type complementary to the first conductivity type arranged in the mesa region adjacent to the first trench, and a second control region of the second conductivity type arranged in the mesa region adjacent to the second trench. The mesa channel region is arranged, in the first lateral direction, between the first control region and the second control region. Each of the first and second trenches includes a gate or source electrode and a bottom electrode, the gate or source electrode (1131, 1132) being arranged between the bottom electrode and the first surface.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of trench JFETs and together with the description serve to explain principles of the examples. Further examples are described in the following detailed description and the claims.

FIG. 1 is a schematic and exemplary cross-sectional view of one example of a trench JFET having a mesa channel region confined by control regions that are electrically coupled to different contacts.

FIG. 2 is a schematic and exemplary cross-sectional view of one example of a trench JFET having a top and bottom electrode in the trenches.

FIG. 3 is a schematic and exemplary cross-sectional view of one example of a trench JFET that is based on the trench JFET according to FIG. 1 and includes a conductive liner adjoining the control region at a bottom part of the trenches.

FIG. 4 is a schematic and exemplary cross-sectional view of one example of a trench JFET that is based on the trench JFET according to FIG. 2 and includes conductive liners adjoining the control regions at a bottom part and at sidewalls of the trenches.

FIG. 5 is a schematic and exemplary cross-sectional view of one example of a trench JFET that is based on the trench JFET according to FIG. 1 and includes a superjunction structure.

FIG. 6 is a schematic and exemplary cross-sectional view of one example of a trench JFET that is based on the trench JFET according to FIG. 1 and includes a measure for electrically deactivating a mesa channel region.

FIG. 7 is a schematic and exemplary cross-sectional view of one example of a trench JFET that is based on the trench JFET according to FIG. 1 and includes mesa regions having different widths.

FIG. 8 is a schematic and exemplary cross-sectional view of another example of a trench JFET that includes a superjunction structure.

FIG. 9 is a schematic and exemplary cross-sectional view of one example of a trench JFET that is based on the trench JFET according to FIG. 8.

FIG. 10 is a schematic and exemplary cross-sectional view of one example of a trench JFET that is based on the trench JFET according to FIG. 9.

FIG. 11 is a schematic and exemplary cross-sectional view of another example of a trench JFET that includes a superjunction structure.

FIG. 12 is a schematic and exemplary cross-sectional view of one example of a trench JFET that is based on the trench JFET according to FIG. 11.

FIGS. 13A-13F illustrate one example of a method form forming a trench JFET according to FIG. 12.

FIG. 14 is a schematic and exemplary cross-sectional view of one example of a trench JFET that is based on the trench JFET according to FIG. 11.

### DETAILED DESCRIPTION

In the following detailed description, reference is made to the accompanying drawings, which form a part hereof and in which are shown by way of illustrations specific examples of trench JFETs. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” describes a permanent low-resistive connection between electrically connected elements, for example a direct contact between the concerned elements or a low-resistive connection via a metal and/or heavily doped semiconductor material. The term “electrically coupled” includes that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact is a non-rectifying electrical junction.

Ranges given for physical dimensions include the boundary values. For example, a range for a parameter y from a to b reads as a≤y≤b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

An example of a vertical junction field effect transistor, VJFET, includes a mesa region confined by first and second trenches along a first lateral direction. This type of vertical JFET may also be referred to as trench JFET. The first and second trenches extend into a semi-conductor body from a first surface of the semiconductor body. The trench JFET further includes a mesa channel region of a first conductivity type that may be confined, along the first lateral direction, by first and second control regions of a second conductivity type. A first pn junction is defined by the mesa channel region and the first control region. A second pn junction is defined by the mesa channel region and the second control region. The first control region is electrically coupled to a source contact, and the second control region is electrically coupled to a gate contact.

The first lateral direction may be a transverse direction of the mesa region that may be perpendicular to a second lateral direction. The second lateral direction may be a longitudinal direction of the mesa region, for example. For example, a width of the mesa region or a width of the first and second trenches may be measured along the first lateral direction, for example.

The trench JFET may be part of an integrated circuit or may define a discrete semiconductor device or a semiconductor module, for example. For example, the trench JFET may be a trenched and implanted vertical-channel JFET, TI-VJFET. In a vertical-channel JFET, a load current flow is between a first load contact over the first surface of the semiconductor body and a second load contact over a second surface opposite to the first surface along the vertical direction. In the vertical-channel JFET, a load current may flow along the vertical direction perpendicular to the first and/or second surface.

The first surface may be a front surface or a top surface of the semiconductor body, and the second surface may be a back surface or a rear surface of the semiconductor body, for example. For example, the semiconductor body may be attached to a lead frame via the second surface, for example. Over the first surface of the semiconductor body, bond pads may be arranged and bond wires may be bonded on the bond pads, for example.

The semiconductor body may include or consist of a semiconductor material from the group IV elemental semiconductors, IV-IV compound semiconductor material, III-V compound semiconductor material, or II-VI compound semiconductor material. Examples of semiconductor materials from the group IV elemental semiconductors include, inter alia, silicon (Si) and germanium (Ge). Examples of IV-IV compound semiconductor materials include, inter alia, silicon carbide (SiC) and silicon germanium (SiGe). Examples of III-V compound semiconductor material include, inter alia, gallium arsenide (GaAs), gallium nitride (GaN), gallium phosphide (GaP), indium phosphide (InP), indium gallium nitride (InGaN) and indium gallium arsenide (InGaAs). Examples of II-VI compound semiconductor materials include, inter alia, cadmium telluride (CdTe), mercury-cadmium-telluride (CdHgTe), and cadmium magnesium telluride (CdMgTe). For example, the semiconductor body may a crystalline SiC semiconductor substrate having none, one or more SiC layers formed thereon. For example, the silicon carbide crystal may have a hexagonal polytype, e.g., 4H or 6H. The silicon carbide semiconductor body may be homogeneously doped or may include differently doped SiC layer portions. The silicon carbide semiconductor body may include one or more layers from another material. For example, the layers from another material may be embedded in the crystalline silicon carbide substrate. The silicon carbide semiconductor substrate may have two essentially parallel main surfaces of the same shape and size and a lateral surface area connecting the edges of the two main surfaces.

The trench JFET may be configured to conduct a current of more than 1 A, more than 10 A, or even more than 100 A. For example, the trench JFET may be designed to include a transistor cell array of a plurality of transistor cells having a same or similar layout. The transistor cell array may be a 1-dimensional or a 2-dimensional regular arrangement of the plurality of transistor cells. For example, the plurality of transistor cells of the transistor cell array may be electrically connected in parallel. For example, source regions of the plurality of transistor cells of the trench JFET transistor cell array may be electrically connected together. Likewise, drain regions of the plurality of transistor cells of the trench JFET transistor cell array may be electrically connected together. For example, gate regions of the plurality of transistor cells of the trench JFET transistor cell array may be electrically connected together. A transistor cell of the transistor cell array or a part thereof, e.g. the gate region, may be designed in the shape of a stripe, a polygon, a circle or an oval, for example.

A number of transistor cells of the transistor cell array may depend on the maximum load current, for example. For example, a number of transistor cells of the transistor cell array may be larger than 100, or larger than 1000, or even larger than 10000, for example. The trench JFET may be further configured to block a voltage between the load electrodes, e.g. between drain and source of the trench JFET, of more than 60V, 100V, 400 V, 650V, 1.2 kV, 1.7 kV, 3.3 kV, 4.5 kV, 5.5 kV, 6 kV, 6.5 kV, 10 kV. The blocking voltage may correspond to a voltage class specified in a datasheet of the trench JFET, for example. The blocking voltage of the trench JFET may be adjusted by an impurity concentration and/or a vertical extension of a drift zone in the semiconductor body. A doping concentration of the drift zone may vary along a lateral and/or vertical direction, e.g. vary gradually or in steps increase or decrease with increasing distance to the first surface at least in portions of its vertical extension. In case of superjunction devices, the doping type may vary, e.g. alternate, along the lateral direction, for example. According to other examples the impurity concentration in the drift zone may be approximately uniform. For trench JFETs based on silicon, a mean impurity concentration in the drift zone may be between 2×10¹² cm⁻³ and 1×10¹⁷ cm⁻³, for example in a range from 5×10¹² cm⁻³ to 1×10¹⁵ cm⁻³ or to 2×10¹⁵ cm⁻³. In the case of a trench JFET based on SiC, a mean impurity concentration in the drift zone may be between 5×10¹⁴ cm⁻³ and 1×10¹⁷ cm⁻³, for example in a range from 1×10¹⁵ cm⁻³ to 5×10¹⁶ cm⁻³. A vertical extension of the drift zone may depend on voltage blocking requirements, e.g. a specified voltage class, of the trench JFET. When operating the trench JFET in voltage blocking mode, a space charge region may vertically extend partly or totally through the drift zone depending on the blocking voltage applied to the trench JFET.

The source contact and the drain contact may be part of a wiring area over the semiconductor body. The wiring area may include one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric structure may be arranged. Contact plug(s) or contact line(s) may be formed in openings in the interlayer dielectric structure to electrically connect parts, e.g. metal lines or contact areas, of different wiring levels to one another. The source contact may be formed by one or more elements of the wiring area over the first surface. Likewise, the drain contact may be formed by one or more elements of the wiring area over the second surface.

For example, a doping concentration in the mesa channel region may be set by in-situ doping with dopants of the first conductivity type when forming a semiconductor layer on a substrate, e.g. by a layer deposition technique. The doping concentration in the mesa channel region may, in addition or as an alternative, be set by ion implantation of dopants of the first conductivity type through a sidewall of the first trench and/or a sidewall of the second trench, e.g. by one or more tilted ion implantation processes.

For example, the first and second control regions of the second conductivity type may be formed by ion implantation of dopants of the second conductivity type through a sidewall and, optionally, through a bottom side of each of the first and second trenches.

For example, after forming the mesa channel region and the first and second control regions, a trench structure may be formed in each of the first and second trenches. The trench structure may include a contact material that may be formed of one or more conductive materials, e.g. metal, metal silicide, metal compound, highly doped semiconductor material such as highly doped polycrystalline silicon. For example, the contact material may be a single layer, e.g. a highly doped polycrystalline layer, or a stack of layers. For example, the trench structure may further include a dielectric structure. The dielectric structure may include a plurality of merged dielectric parts that may differ in material, for example. The dielectric structure may be or may include an insulating material such as an oxide, e.g., SiO₂, a nitride, e.g., Si₃N₄, a high-k dielectric, or a low-k dielectric, or any combination thereof. For example, the dielectric structure may be formed as a disposed oxide (TEOS). The contact material of the trench structure in the first trench may be electrically connected to the first control region of the second conductivity type via the bottom side and/or the sidewall of the trench structure. For example, the contact material may be electrically connected to the first control region through an opening in the dielectric structure of the trench structure, e.g. at a bottom side of the trench structure. Likewise, the contact material of the trench structure in the second trench may be electrically connected to the second control region of the second conductivity type via the bottom side and/or the sidewall of the trench structure. For example, the contact material may be electrically connected to the second control region through an opening in the dielectric structure of the trench structure, e.g. at a bottom side of the trench structure. Although the trench structures in the first and second trenches may be processed together, the contact material of the trench structure in the first trench may be electrically coupled to the source contact or electrode, and the contact material of the trench structure in the second trench may be electrically coupled to the gate contact.

For example, dopants in a semiconductor body comprising SiC may include Al, B, Be, Ga, or any combination thereof for p-type doping, and N, P, or any combination thereof for n-type doping. For example, dopants in a semiconductor body comprising Si may include Al, B, Ga, In, or any combination thereof for p-type doping, and P, As, Sb, hydrogen-related donors, or any combination thereof for n-type doping.

For example, the trench JFET may further include an edge termination area that laterally separates an active trench JFET area and a field-free area and may completely surround the active trench JFET area laterally. In a blocking mode or in a reverse biased mode of the trench JFET, the blocking voltage between the active trench JFET area and the field-free area laterally drops across a termination structure in the edge termination area. The edge termination area may have a higher or a slightly lower voltage blocking capability than the active trench JFET area. The termination structure in the edge termination area may include or may a junction termination extension (JTE) with or without a variation of lateral doping (VLD), one or more laterally separated guard rings, or any combination thereof.

By electrically coupling the first control region to the source contact instead of, for example, the gate contact, the gate-to-drain capacitance Cgd and the ratio of Cgd to the gate-to-source capacitance Cgs may be reduced. This may allow for improving the switching efficiency and switching speed by reducing the amount of gate charges that have to be removed when switching. This may allow for improving the ease-of-use of trench JFETs, as well.

For example, the first trench may include a dielectric trench filling structure.

Functional or structural configuration details described with respect to the exemplary trench JFET above likewise apply to another example of a trench junction field effect transistor that includes a mesa region confined by first and second trenches along a first lateral direction. The first and second trenches extend into a semiconductor body from a first surface of the semiconductor body. The trench JFET further includes a mesa channel region of a first conductivity type confined, along the first lateral direction, by first and second control regions of a second conductivity type. A first pn junction is defined by the mesa channel region and the first control region. A second pn junction is defined by the mesa channel region and the second control region. Each of the first and second trenches includes a gate or source electrode and a bottom electrode. The gate or source electrode is arranged between the bottom electrode and the first surface.

For example, the trench JET further includes a dielectric separation region, e.g. an oxide, arranged between the bottom electrode and the gate or source electrode.

For example, each of the first and second control regions may be divided into a top part and a bottom part. The top part and the bottom part may be vertically spaced from one another by an intermediate separation region of the first conductivity type. This may allow for avoiding a short circuit between the bottom electrode and the gate or source electrode arranged above the bottom electrode, for example.

For example, the intermediate separation region may adjoin to the dielectric separation region along the first lateral direction.

For example, the trench JFET may further include a first conductive liner at a sidewall portion of at least one of the first and second trenches. The first conductive liner may be laterally arranged between a trench filling material in the at least one of the first and second trenches, e.g. a conductive material of the gate or source electrode, and a corresponding one of the first and second control regions. The first conductive liner may improve or enable an ohmic contact between the trench filling material in the at least one of the first and second trenches and a corresponding one of the first and second control regions. Moreover, the first conductive liner may improve a transverse conductivity along a longitudinal direction of the at least one of the first and second trenches. This may contribute to reducing resistive losses from the gate electrode in the trenches to a gate pad, for example. For example, the first conductive liner may be formed by a metal such as Ni or Ti that may further include additives, e.g. Al.

For example, the trench JFET may further include a second conductive liner at a bottom portion of at least one of the first and second trenches. The second conductive liner may be vertically arranged between a trench filling material in the at least one of the first and second trenches and a corresponding one of the first and second control regions. The second conductive liner may improve an ohmic contact between the trench filling material in the at least one of the first and second trenches, e.g. a conductive material of the bottom electrode, and a corresponding one of the first and second control regions. Moreover, the first conductive liner may improve a transverse conductivity along a longitudinal direction of the at least one of the first and second trenches. This may contribute to reducing resistive losses from the bottom electrode in the trenches to a corresponding contact area, e.g. a source or gate contact, for example. For example, the second conductive liner may be formed by a metal such as Ni or Ti that may further include additives, e.g. Al.

For example, the trench JFET may further include a superjunction structure arranged between a bottom side of the first and second trenches and a second surface of the semiconductor body opposite to the first surface.

For example, the superjunction structure may include a first SJ region of the first conductivity type, and a second SJ region of the second conductivity type. The first SJ region may be electrically coupled to a drain contact at the second surface of the semiconductor body and to the source contact at the first surface of the semiconductor body. The second SJ region may be electrically coupled to the first and second control regions. For example, a top side of the second SJ region may adjoin to a bottom side of the first and second control regions. For example, doping concentration profiles of the second SJ region and the first and second control regions may overlap with one another.

For example, a vertical extension of the superjunction structure may range from 50% to 2000% of a vertical extension of the first and second trenches.

For example, the trench JFET may further include a source region of the second conductivity type arranged on the one of opposite sidewalls of the mesa region that adjoins to the second trench. This may allow for improving an ohmic contact between the mesa channel region and the source contact, for example.

For example, the trench JFET may further include a second mesa region. The second mesa region may be wider than the mesa region. The second trench is laterally confined by the mesa region and the second mesa region. Mesa regions having different widths may allow for counteracting offsets in pinch-off voltages arising from different pinch-off behavior that may be caused by control regions having different potentials, for example.

For example, an extent of the mesa region along the first lateral direction may range from 200 nm to 2 μm.

For example, along the first lateral direction, the mesa channel region may include, first, second and third mesa channel sub-regions having a same extent along the first lateral direction. A concentration of dopants of the first conductivity type averaged along the first lateral direction in the second mesa channel sub-region may be larger than a concentration of dopants of the first conductivity type averaged along the first lateral direction in each of the first and third mesa channel sub-regions. By providing a trench JFET having the above relation with respect to concentration of dopants in the mesa channel region, compensation of a channel charge amount caused by an overlap of doping profiles of the first and second control regions and the mesa channel region may be reduced. This may allow for stabilizing the charge amount in the mesa channel. Thus, variability of a pinch off voltage or threshold voltage of the trench JFET may be reduced. This may further improve the ease-of-use of trench JFETs.

The examples and features described above and below may be combined.

Functional and structural details described with respect to the examples above shall likewise apply to the exemplary examples illustrated in the Figs. and described further below.

In the following, further examples of trench JFETs are explained in connection with the accompanying drawings. Functional and structural details described with respect to the examples above shall likewise apply to the exemplary embodiments illustrated in the Figs. and described further below. In the illustrated examples, the first conductivity is n-type and the second conductivity type is p-type for an n-channel trench JFET. However, the first conductivity type may also be p-type and the second conductivity type may be n-type for a p-channel trench JFET.

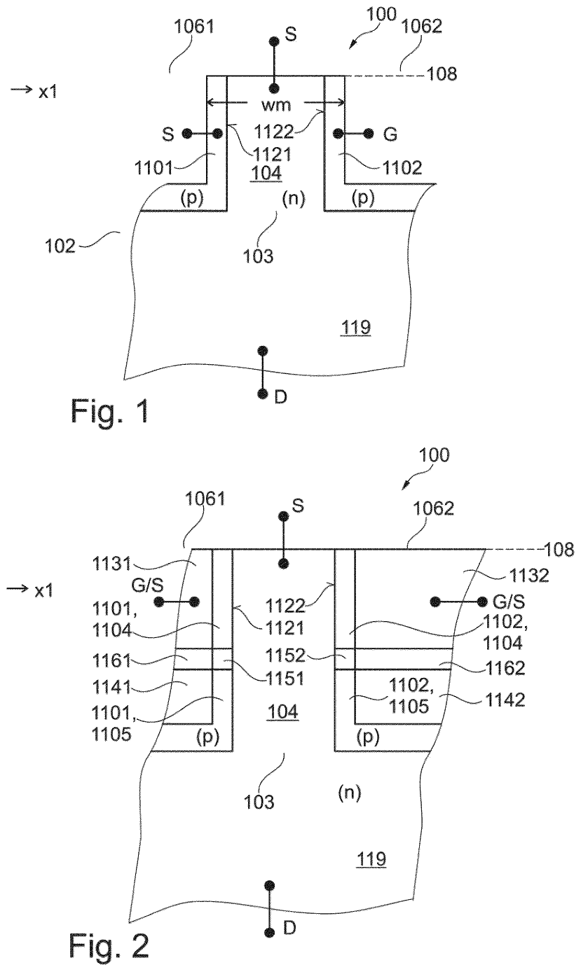

FIG. 1 schematically and exemplarily shows a cross-sectional view of a configuration example of a trench JFET 100.

The trench JFET 100 includes a mesa region 103 confined by first and second trenches 1061, 1062 along a first lateral direction x1 of a semiconductor body 100. The first and second trenches 1061, 1062 extend into the semiconductor body 102 from a first surface 108 of the semiconductor body 102. A doped mesa channel region 104 of a first conductivity type is confined, along the first lateral direction x1, by first and second control regions 1101, 1102 of a second conductivity type complementary to the first conductivity type. According to one example, the first conductivity type is an n-type, so that the mesa channel region 104 is n-doped, and the second conductivity type is a p-type, so that the control regions 1101, 1102 are p-doped.

In each case, a first pn junction 1121 is defined by the mesa channel region 104 and the first control region 1101, and a second pn junction 1122 is defined by the mesa channel region 104 and the second control region 1102. To form the first pn junction, the first control region 1101 may adjoin the mesa channel region 104. This, however, is only an example. It is also possible that the first control region 1101 is spaced apart from the mesa channel region 104 in the first lateral direction x1 and that a region having a lower doping concentration than each of the first control region 1101 and the mesa channel region 104 is arranged between the first control region 1101 and the mesa channel region 104. The further region may have the first conductivity type, the second conductivity type, or may be intrinsic. In each case, a pn junction is formed in a region between the first control region 1101 and the mesa channel region 104, so that the pn junction is arranged between the first control region 1101 and the mesa channel region 104.

Equivalently, to form the second PN junction, the second control region 1102 may adjoin the mesa trial region 104. Alternatively, the second control region 1102 may be spaced apart from the mesa channel region 104 in the first lateral direction x1, so that a region having a lower doping concentration than each of the second control region 1102 and the mesa channel region 104 is arranged between the second control region 1102 and the mesa channel region 104. The further region may have the first conductivity type, the second conductivity type, or may be intrinsic. In each case, a pn junction is formed in a region between the second control region 1102 and the mesa channel region 104, so that the pn junction is arranged between the second control region 1102 and the mesa channel region 104.

The mesa channel region 104 is electrically coupled, e.g. via a drift zone 119, to a drain contact D at a second surface of the semiconductor body. The drift zone 119 is of the first conductivity type, for example. The mesa channel region 104 is also electrically coupled to a source contact S at the first surface 108 of the semiconductor body 102, e.g. via a source region 124 at the first surface 108. The source region 124 is of the first conductivity type and may have a higher doping concentration than the drift zone 119.

For example, an extent wm of the mesa region 103 along the first lateral direction x1 may range from 200 nm to 2 μm, or from 300 nm to 1.6 μm, or from 400 nm to 1.2 μm.

The first control region 1101 is electrically coupled to the source contact S, e.g. via a conductive material as part of a filling material in the first trench 1061. As an alternative, the first control region 1101 may also be electrically coupled to the source contact S via a contact on the first control region 1101 at the first surface 108. In this case, the first trench 1101 may include a dielectric trench filling structure, for example.

The second control region 1102 is electrically coupled to a gate contact G via a conductive filling material (e.g. a gate electrode) in the second trench 1062.

FIG. 2 schematically and exemplarily shows a cross-sectional view of another configuration example of a trench JFET 100.

Each of the first and second trenches 1061, 1062 includes a gate or source electrode 1131, 1132 and a bottom electrode 1141, 1142. The gate or source electrode 1131, 1132 is arranged between the bottom electrode 1141, 1142 and the first surface 108 and is electrically coupled to a gate or source contact G/S.

A capacitive behavior, e.g. C_{GD}, may be adjusted via a potential applied to the bottom electrode 1141, 1142. For example, the bottom electrode 1141 in the first trench 1061 may be electrically coupled the gate contact G and the bottom electrode 1142 in the second trench 1062 may be electrically coupled to the source contact S, or vice versa. Both bottom electrodes 1141, 1142 may also be electrically coupled to the gate contact G, or to the source contact S. While the capacitive behavior may be adjusted via the potential of each of the bottom electrodes in the trenches 1061, 1062, the current behavior may be adjusted via the potential, e.g. gate or source potential, applied to each of the gate or source electrodes 1131, 1132 in the trenches. By applying a source potential to one of the gate or source electrodes 1131, 1132, the respective trench may be deactivated with respect to control of channel conductivity, for example.

A dielectric separation region 1161, 1162 is arranged between the bottom electrode 1141, 1142 and the gate or source electrode 1131, 1132 for electrically separating the gate or source electrode 1131, 1132 and the bottom electrode 1141, 1142 in each of the trenches 1061, 1062.

Each of the first and second p-doped control regions 1101, 1102 has a top part 1104 and a bottom part 1105. The top part 1104 and the bottom part 1105 are vertically spaced from one another by an intermediate n-doped separation region 1151, 1152. Between the intermediate n-doped separation region 1151, 1152 and the p-doped first and second p-doped control regions 1101, 1102, a pn junction isolation is formed for avoiding a short-circuit between the source or gate electrode 1131, 1132 and the bottom electrode 1141, 1142. The intermediate separation region 1151, 1152 adjoins to the dielectric separation region 1161, 1162 along the first lateral direction x1.

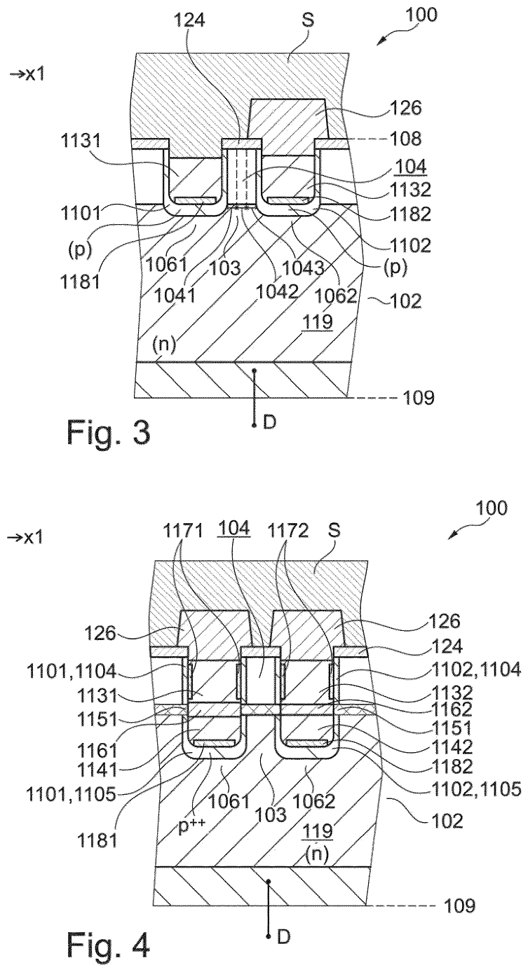

FIG. 3 schematically and exemplarily shows a cross-sectional view of another configuration example of a trench JFET 100 that is related to the example illustrated in FIG. 1.

The trench JFET 100 of FIG. 3 includes a conductive liner 1181, 1182 at a bottom portion of the first and second trenches 1061, 1062. The conductive liner 1181, 1182 is vertically arranged between the gate or source electrode 1131, 1132 in the first and second trenches 1061, 1062 and a corresponding one of the first and second control regions 1101, 1102. The first control region 1101 is electrically connected to the source contact S via the gate or source electrode 1131 in the first trench 1061. The second control region 1102 is electrically connected to a gate contact (not illustrated in FIG. 3) via the gate or source electrode 1132 in the second trench 1062. An interlayer dielectric 126 is arranged on the gate or source electrode 1132. The mesa channel region 104 is electrically coupled to the source contact S at the first surface 108 of the semiconductor body 102 via an n⁺-doped source region 124 at the first surface 108.

Along the first lateral direction x1, the mesa channel region 104 includes, first, second and third mesa channel sub-regions 1041, 1042, 1043 having a same extent along the first lateral direction x1. A concentration of n-type dopants averaged along the first lateral direction x1 in the second mesa channel sub-region 1042 is larger than a concentration of n-type dopants averaged along the first lateral direction x1 in each of the first and third mesa channel sub-regions 1041, 1043.

FIG. 4 schematically and exemplarily shows a cross-sectional view of another configuration example of a trench JFET 100 that is related to the example illustrated in FIG. 2.

Similar to the configuration example of FIG. 3, the trench JFET 100 of FIG. 4 includes a conductive liner 1181, 1182 at a bottom portion of the first and second trenches 1061, 1062. The conductive liner 1181, 1182 is vertically arranged between the bottom electrode 1141, 1142 and a corresponding one of the first and second control regions 1101, 1102.

The trench JFET 100 further includes the mesa channel region 104 having the first, second and third mesa channel sub-regions 1041, 1042, 1043 as described with reference to the configuration example of FIG. 3.

The trench JFET further includes a conductive liner 1171, 1172 at a sidewall portion of the first and second trenches 1061, 1062. The conductive liner 1171, 1172 is laterally arranged between a trench filling material, e.g. the gate or source electrode 1131, 1132, in the first and second trenches 1061, 1062 and a corresponding one of the first and second control regions 1101, 1102.

FIGS. 1-4 each illustrate only one mesa region 103 arranged between a first trench 1061 and a second trench 1062. This is just for illustration purposes. It should be noted that the trench JFET according to each example explained herein may include a plurality of first and second trenches 1061, 1062 that are arranged alternatingly in the first lateral direction x1, so that the trench JFET includes a plurality of mesa regions 103 that are spaced apart from each other in the first lateral direction x1. Neighboring mesa regions 103 are separated from one another either by a first trench 1061 or a second trench 1062. Accordingly, the trench JFET includes a plurality of first control regions 1101 each adjoining a respective first trench 1061 and connected to the source contact S, and a plurality of second control regions 1102 each adjoining a respective second trench 1062 and connected to the gate contact G.

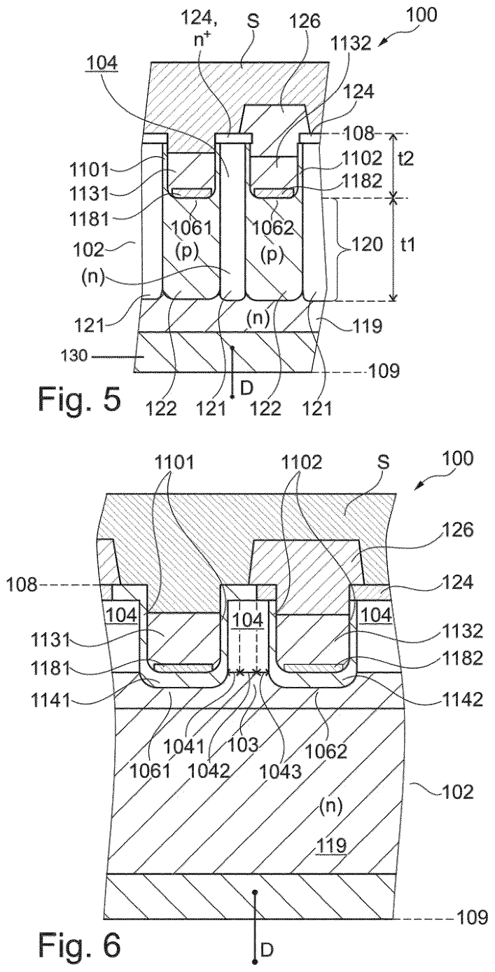

FIG. 5 schematically and exemplarily shows a cross-sectional view of another example of a trench JFET 100 that is related to the example illustrated in FIG. 1.

Instead of only a drift zone 119 of the first conductivity type, the trench JFET 100 according to FIG. 5 includes a superjunction, SJ, structure 120 arranged between a bottom side of the first and second trenches 1061, 1062 and a second surface 109 of the semiconductor body 102 opposite to the first surface 108. More specifically, the SJ structure 120 may be arranged between bottoms of the first and second trenches 1061, 1062 and a drain region 130 of the first conductivity type. The drain region 130 is connected to the drain contact D.

The SJ structure 120 includes first SJ regions 121 of the first conductivity type and second SJ regions 122 of the second conductivity type. In the SJ structure 120, the first SJ regions 121 may also be referred to as drift regions which together form at least a portion of a drift zone of the trench JFET. The second SJ regions 122 may also be referred to as compensation regions. Between the drain region 130 and the SJ structure 120 a doped region 119′ of the first conductivity type may be arranged. This doped region 119′ may have a lower doping concentration than the drain region 130. The doped region 119′ may form a further portion of the drift zone and/or may form a buffer region. The doped region 119′ may include two or more differently doped regions of the first conductivity type that arranged one above the other between the drain region 130 and the SJ region 120.

In the superjunction structure 120, the plurality of first SJ regions 121 of the first conductivity type and the plurality of second SJ regions 122 of the second conductivity type are arranged alternatingly in the first lateral direction x1. Each of the first SJ regions 121 is electrically coupled to the drain region 130 and the drain contact D connected to the drain region 130. As illustrated in FIG. 5, the first SJ regions 121 may be coupled to the drain region 130 through the doped region 119′ of the first conductivity type. Furthermore, each of the first SJ regions 121 is electrically coupled to the source contact S at the first surface 108 of the semi-conductor body 102 via the mesa channel region 104 and the source region 124.

In the example illustrated in FIG. 5, the second SJ regions 122 include a first group of second SJ regions and a second group of second SJ regions. Each of the second SJ regions 122 of the first group is electrically coupled to a respective first control region 1101, and each of the second SJ regions of the second group is electrically coupled to a respective second control region 1102.

For example, a vertical extension t1 of the superjunction structure 120 may range from 50% to 2000% of a vertical extension t2 of the first and second trenches 1061, 1062.

The operating principle of the trench JFET according to FIG. 5 is briefly explained in the following. For illustration purposes it is assumed that the first conductivity type, which is the conductivity type of the mesa channel region 124, the first SJ regions 121, the drain region 130, and the region 119′ between the drain region 130 and the superjunction region 120 is an n-type and that the second conductivity type, which is the conductivity type of the first and second control regions 1101, 1102 and the second SJ regions 122 is a p-type.

In this example, the JFET is in an on-state (conducting state) when a drive voltage (gate-source voltage) between the gate contact G (not illustrated in FIG. 5) and the source contact S is higher than a negative threshold voltage of the trench JFET, so that a current can flow from the drain contact D via the drain region 130, the region 119′, the first SJ regions 121, the mesa channel region 104, and the source region 124 to the source contact S. The JFET is in the off-state (blocking stage) when the drive voltage is lower (more negative) than the threshold voltage. In this case, a space charge region (depletion region) expands in the mesa channel region 104 beginning at the pn junction between the mesa channel region 104 and the second control region 1102, which is that one of the first and second control regions 1101, 1102 that is connected to the gate contact G. The JFET is in the off-state when the drive voltage is such that the mesa channel region 104 is entirely depleted of charge carriers between the first and second control regions 1101, 1102.

Furthermore, in the off-state, each first SJ region 121 is depleted of charge carriers due to one of the neighboring second SJ regions 122 being coupled to the source contact S via the first control region 1101 and the other one of the neighboring second SJ regions 122 being coupled to the gate contact G via the second control region 1102.

As compared to a conventional trench JFET, in which the control regions along both sidewalls of a mesa region are connected to the gate node, the threshold voltage of the transistor device according to FIG. 5 is more negative. On the other hand, the transistor device according to FIG. 5 has a lower gate-drain capacitance because not each of the control regions is connected to the gate contact G but some of the control regions (the first control regions 1101) are connected to the source node.

FIG. 6 schematically and exemplarily shows a cross-sectional view of another configuration example of a trench JFET 100 that is related to the example illustrated in FIG. 1.

The n⁺-doped source region 124 is merely arranged on the one of opposite sidewalls of the mesa region 103 that adjoins to the second trench 1062. Thus, the n⁺-doped source region 124 is omitted on the sidewall and on the top side portion of the mesa region 103 that adjoins to the first trench 1061 that adjoins to the source contact S. Thereby, the control of a channel conductivity is deactivated in the mesa region 103 at the sidewall of the second trench 1062 since the source region 124 adjoins to the intermediate dielectric 126 but not to the source contact S.

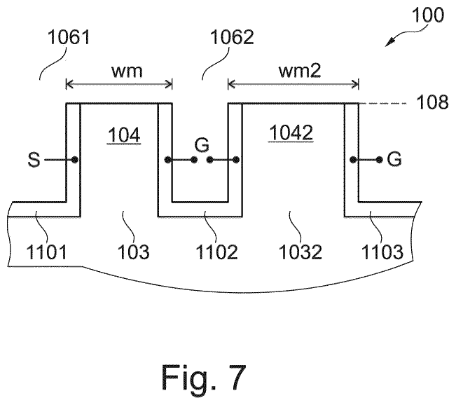

FIG. 7 schematically and exemplarily shows a cross-sectional view of another configuration example of a trench JFET 100 that is related to the example illustrated in FIG. 1.

The trench JFET 100 includes a second mesa region 1032 having a width wm2. The second mesa region 1032 is wider than the mesa region 103, i.e. wm2>wm. The second mesa region 1032 adjoins to the second control region 1102 and to a third control region 1103. The second and the third control region 1102, 1103 are electrically coupled to the gate contact G. Thus, a second mesa channel region 1042 in the second mesa region 1032 is pinched-off via space charge regions from opposite sidewalls of the second mesa region 1032. In the mesa region 103, the mesa channel region 104 is pinched-off via only one of opposite space charge regions since the first control region 1101 is electrically coupled to the source contact S and the expansion of the related space charge region cannot be controlled via a voltage applied to the gate contact G.

The configuration examples of FIGS. 6 and 7 illustrate measures for counteracting an offset in pinch-off voltages (threshold voltages) that may occur when applying different voltages to the control regions confining the mesa channel regions. Different voltages, e.g. gate or source voltage, may be applied to the control regions for adjusting the capacitive behavior of the trench JFET, for example.

In the superjunction trench JFET according to FIG. 5, the first SJ region 121, in which a current flows between the mesa channel region 104 and the drain region 130 in the on-state, adjoins the mesa channel region 104 along the entire width of the mesa channel region 104. The width of the mesa channel region 104 is the dimension of the mesa channel region 104 in the first lateral direction x1. In order to operate this JFET in the off-state, the mesa channel region 104 is to be depleted of charge carriers over its entire width by applying a suitable negative drive voltage between the gate contact G connected to the second control region 1102 and the source contact S connected to the mesa channel region 104.

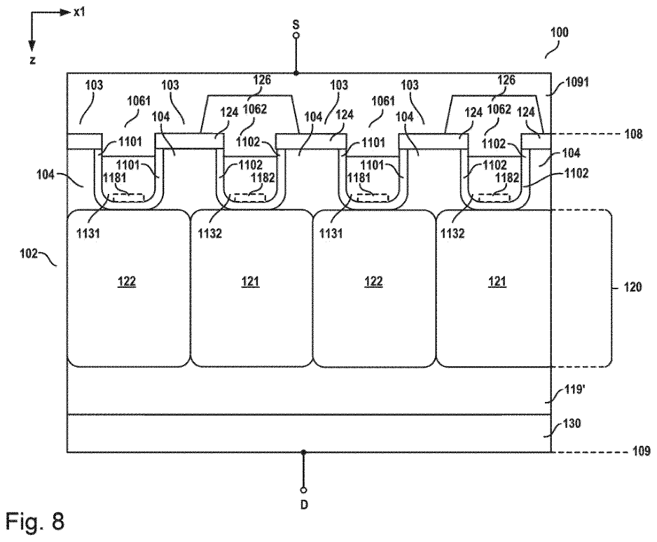

FIG. 8 illustrates a modification of the trench JFET according to FIG. 5. The trench JFET according to FIG. 5 is different from the trench JFET according to FIG. 8 in that the first and second SJ regions 121, 122 of the superjunction structure 120 are offset (shifted) relative to the mesa channel regions 104 such that a pn junction formed between neighboring first and second SJ regions 121, 122 is arranged below the mesa channel region 104 in a vertical direction z of the semiconductor body 102. The “vertical direction z” is a direction of the semiconductor body 102 that is essentially perpendicular to the first and second surface is 108, 109. Thus, in the trench JFET according to FIG. 8, each mesa channel region 104, in the vertical direction z, adjoins a portion of a first SJ region 121 and a portion of a neighboring second SJ region 122. Furthermore, in the trench JFET according to FIG. 8, each first SJ region 121 is arranged below a respective second trench 1062 with a gate electrode 1132 arranged therein, and each second SJ region 122 is arranged below a respective first trench 1061 with a source electrode 1131 arranged therein.

The source electrodes 1131 are connected to a source metallization 1091 which is connected to the source contact S or forms the source contact S, for example. The gate electrodes 1132 are connected to a gate contact G, which is not illustrated in FIG. 8.

In the example illustrated in FIG. 8, neighboring first and second SJ regions 121, 122 adjoin each other. This, however, is only an example. According to another example (not illustrated) neighboring first and second SJ regions 121, 122 are spaced apart from each other in the first lateral direction x1, wherein a region of the first or second conductivity type and having a lower doping concentration than each of the first and second SJ regions 121, such as a doping concentration lower than 5E15 cm⁻³, or an intrinsic region may be arranged between the neighboring first and second SJ regions 121, 122. In each case, the mesa channel region 104 adjoins a portion of one first SJ region 121 and a portion of one second SJ region 122.

Furthermore, referring to FIG. 8, each second SJ region 122 is connected to the source contact S via a respective one of the first control regions 1101, and a respective source electrode 1131. For this, the first control regions 1101 may not only be arranged along sidewalls of the first trenches 1061, but also along bottoms of the first trenches 1061. Each second SJ region 122 is spaced apart from the second control regions 1102.

The operating principle of the trench JFET according to FIG. 8 is similar to the operating principle of the trench JFET according to FIG. 5. In the on-state, a current flows between the drain and source contacts D, S, inter alia, via the first SJ regions 121 and the mesa channel regions 104.

The JFET is in the off-state when the mesa channel region 104 is depleted of charge carriers. The JFET may already be in the off-state when those portions of the mesa channel region 104 are depleted of charge carriers that adjoin the first SJ region 121. A current flow through those portions of the mesa channel region 104 that adjoin the second SJ regions 122 is prevented by a pn junction formed between the second SJ regions 122 and the mesa channel regions 104. This may have the effect that a threshold voltage of the trench JFET according to FIG. 8 may have a lower magnitude (may be less negative) than the threshold voltage of the trench JFET according to FIG. 5.

Furthermore, in the off-state, each first SJ region 121 is depleted of charge carriers because of the first SJ regions 121 being electrically coupled to the drain region 130 and the drain node D, and the second SJ regions 122 being coupled to the source node S. Different from the example illustrated in FIG. 5, in the trench JFET according to FIG. 8, each of the second control regions 1102 is spaced apart from SJ regions 122 and is arranged next to a respective first SJ region 121, so that a pn junction may be arranged between the second control region 1102, and the first SJ region 121. This may help to reduce the gate-drain capacitance as compared to the JFET illustrated FIG. 5.

In the trench JFET according to FIG. 8, the superjunction structure 120 with the first and second SJ regions 121, 122 arranged alternatingly in the first lateral direction x1 may be produced by a conventional multi-epi-multi-implant (MEMI) process. This process includes forming two or more epitaxial layers one above the other, implanting first and second type dopant atoms into each of the epitaxial layers using respective implantation masks, and an annealing process that activates the implanted first and second type dopant atoms in order to form the first and second SJ regions 121, 122. The first and second trenches 1061, 1062 may be formed in an uppermost epitaxial layer formed on top of the epitaxial layers including the superjunction structure 120. The mesa channel regions 104 may be formed by implanting first conductivity type dopant atoms into the uppermost epitaxial layer. The first and second control regions 1101, 1102 may be formed by implanting second conductivity type dopant atoms into sidewalls and the bottoms of the first and second trenches 1061, 1062.

As can be seen from FIG. 8, each mesa region 102 includes a mesa channel region 104 arranged between a first control region 1101 and a second control region 1102. The first control regions 1101 are arranged along both sidewalls (and the bottoms) of the first trenches 1061, and the second control regions 1102 are arranged along both sidewalls (and the bottoms) of the second trenches 1062.

In the example illustrated in FIG. 8 and the following examples, conductive liners 1181, 1182 are optional and, therefore, illustrated in dashed lines.

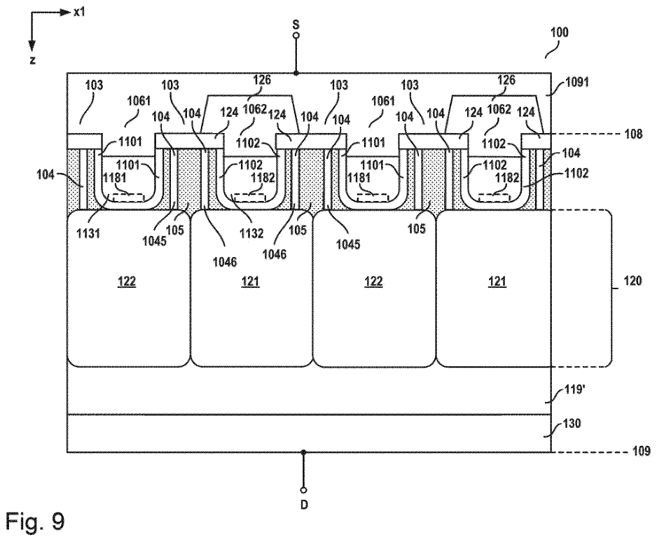

FIG. 9 illustrates a modification of the transistor device according to FIG. 8. In this example, each mesa channel region 104 includes a first region 1045 arranged next to the first control region 1101 in the first lateral direction x1, and a second region 1046 arranged next to the second control region 1102 in the first lateral direction x1. In the vertical direction z, the first region 1045 adjoins a respective second SJ region 122 and the second region 1046 adjoins a respective first SJ region 121. The first and second regions 1045, 1046 are spaced apart from each other in the first lateral direction x1. Between the first and second regions 1045, 1046 a region 105 is arranged that is either of the first or second conductivity type and has a lower doping concentration than each of the first and second regions 1045, 1046, such as lower than 5E15 cm⁻³, or that is intrinsic. The first region 1045 may adjoin the first control region 1101 or, as illustrated, may be spaced apart from the first control region 1101.

Equivalently, the second region 1046 may adjoin the second control region 1102 or, as illustrated, may be spaced apart from the second control region 1102. In the trench JFET according to FIG. 9, both in the on-state and the off-state a current flow through the first region 1045 of the mesa channel region 104 is prevented by the pn junction between the first region 1045 of the mesa channel region 104 and the second SJ region 122.

The first mesa channel regions 1045 may be produced by implanting dopant atoms into sidewalls of the mesa regions before forming the electrodes 1131, 1132 in the first and second trenches 1061, 1062. In this type of process it may save costs to implant dopant atoms into each sidewall of each mesa region 103, thereby forming first and second mesa channel regions 1045, 1046, instead of implanting dopant atoms only into sidewalls of the mesa regions adjoining the second trenches 1062 to only form the second mesa channel regions 1046.

The trench JFET according to FIG. 9 is in the off-state when a gate-source voltage is applied between the gate node G and the source node S that causes the second control region 1102 to deplete the second mesa channel region 1046 of charge carriers.

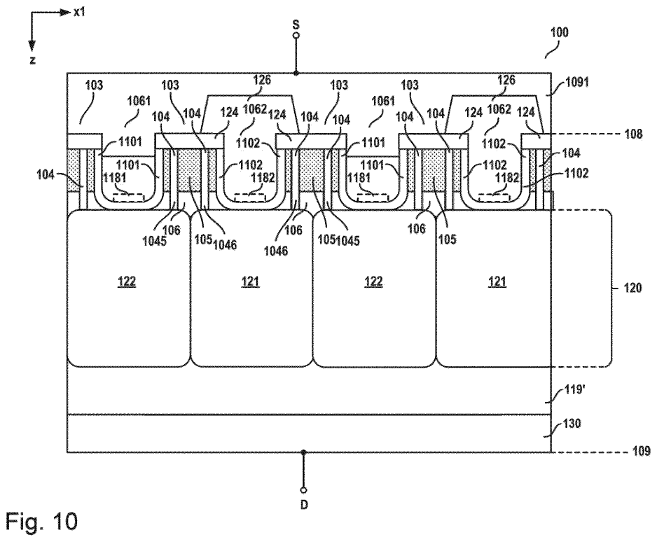

FIG. 10 shows a modification of the trench JFET according to FIG. 9. Compared to the trench JFET according to FIG. 9, the trench JFET according to FIG. 10 further includes a current spreading region 106 arranged at least between the first and second mesa channel regions 1045, 1046 in each mesa region 103. The current spreading region 106 is of the first conductivity type and, in the on-state of the JFET, enables a current flow from the first mesa channel region 1045 to the second mesa channel region 1046. This may help to reduce the on-resistance, which is the electrical resistance of the trench JFET between the drain contact D and the source contact S in the on-state.

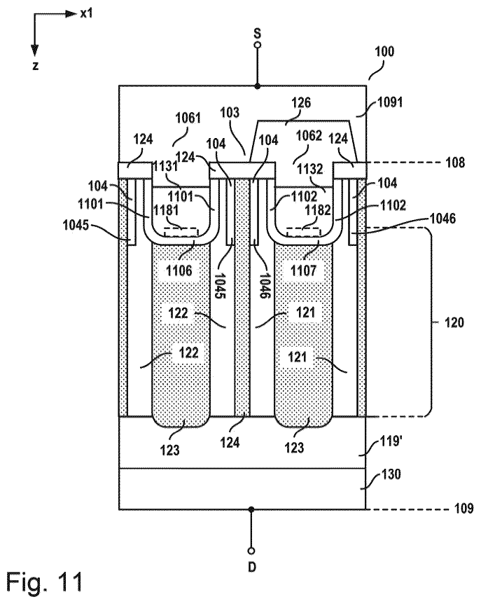

In the trench JFETs according to FIGS. 8-10, the first and second SJ regions 121, 122 are arranged alternatingly in the first lateral direction x1 such that each first SJ region 121 is arranged between two second SJ regions 122 and each second SJ region 122 is arranged between two first SJ regions 121. Another way of alternatingly arranging the first and second SJ regions 121, 122 is illustrated in FIG. 11.

FIG. 11 shows a modification of the trench JFET according to FIG. 10. In this trench JFET, the first and second SJ regions 121, 122 are arranged alternatingly in the first lateral direction x1 in such a way that pairs of neighboring first SJ regions 121 and pairs of neighboring second SJ regions 122 are arranged alternatingly. The first SJ regions 121 of each pair are spaced apart from each other in the first lateral direction x1, and the second SJ regions 122 of each pair are spaced apart from each other in the first lateral direction x1, wherein a semiconductor region 123 is arranged between the SJ regions 121, 122 of each pair. The semiconductor region 123 is of the first or second conductivity type and has a lower doping concentration than each of the first and second SJ regions 121, 122, or is intrinsic.

Referring to FIG. 11, each of the first SJ regions 121, in the vertical direction z, adjoins a respective second mesa channel region 1046, so that in the on-state a current can flow between the drain contact D and the source contact S, inter alia, via the second mesa channel regions 1046 and the first SJ regions 121. Furthermore, each of the second SJ regions 122 adjoins a respective first mesa channel region 1045. Both in the on-state and the off-state a current flow through the first mesa channel regions 1045 is prevented due to a pn junction between the second SJ region 122 and the respective first mesa channel region 1045.

In the trench JFET according to FIG. 11, neighboring first and second SJ regions 121, 122 may adjoin each other. According to another example, as illustrated, neighboring first and second SJ regions 121, 122 may be spaced apart from each other in the first lateral direction x1, wherein a semiconductor region 124 is arranged between the neighboring first and second SJ regions. The semiconductor region 124 is of the first or second conductivity type and has a lower doping concentration than each of the first and second SJ regions 121, 122, or is intrinsic.

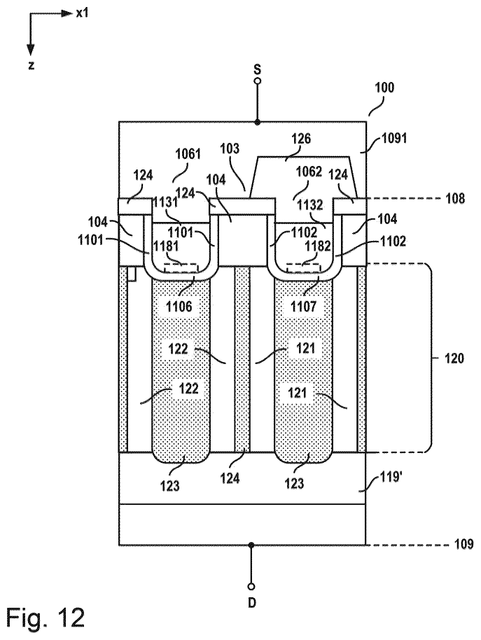

FIG. 12 shows a modification of the trench JFET according to FIG. 11. The trench JFET according to FIG. 12 includes only one mesa channel region 104 in each mesa region 103 which adjoins both the first SJ region 121 and the second SJ region 122 arranged below the respective mesa region 103 in the vertical direction z.

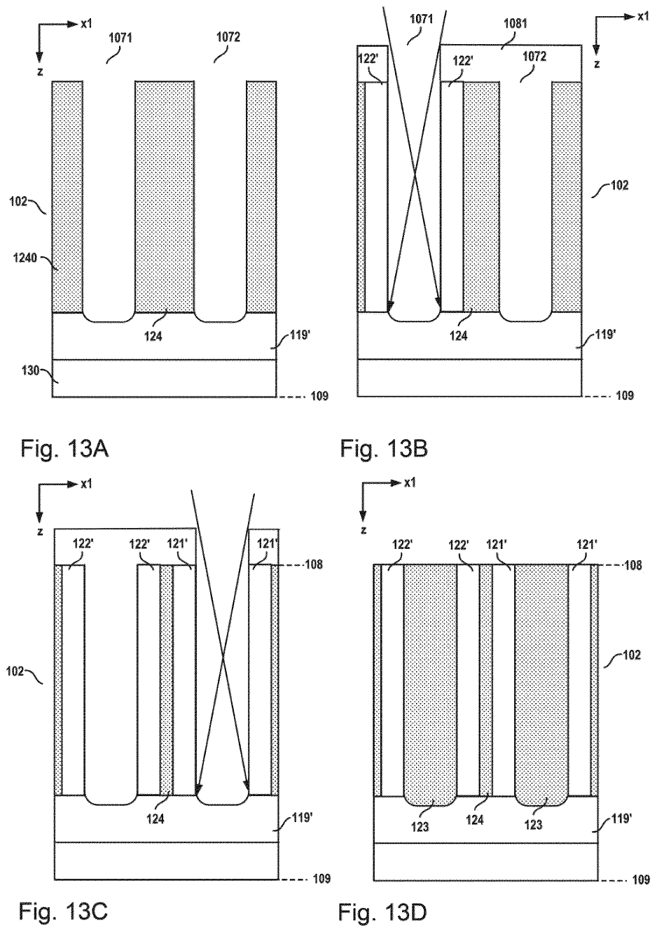

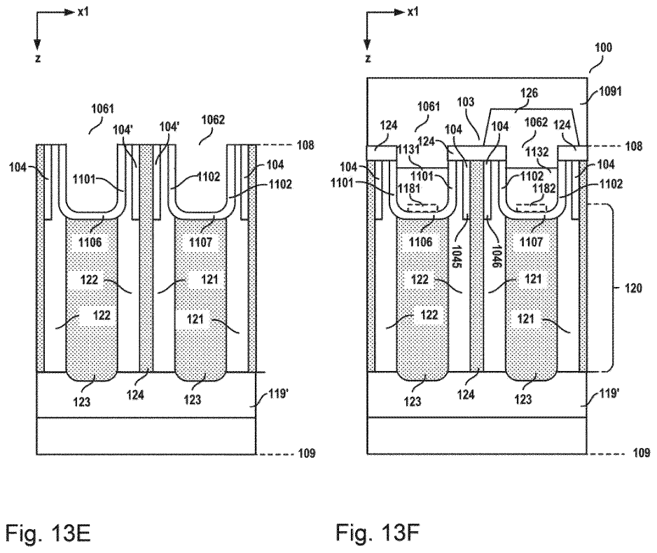

FIGS. 13A-13F schematically illustrate one example of a method for forming a trench JFET of the type illustrated in FIG. 11. Each of FIGS. 13A-13F shows a vertical cross-sectional view of the semiconductor body 102 during different process steps.

Referring to FIG. 13A, the method is based on a semiconductor body 102 that includes the drain region 130, the region 119′ of the first conductivity type, and an epitaxial layer 1240 formed on top of the region 119′. The drain region 130 is formed by a semiconductor substrate, for example. The region 119′ may be formed by one or more epitaxial layers formed on top of the substrate. The epitaxial layer 1240 formed on top of the region 119′ is or lowly doped, for example. According to one example, this includes that a basic doping concentration of the epitaxial layer 1240 is lower than 1E16 cm⁻³, lower than 5E15 cm⁻³, or lower than 1E15 cm⁻³.

Referring to FIG. 13A, the method includes forming first and second trenches 1071, 1072 in the epitaxial layer 1240. The first and second trenches 1071, 1072 may extend through the epitaxial layer 1240 into the region 119′. Forming the first and second trenches 1071, 1072 may include a conventional etching process using an etch mask (not illustrated in FIG. 13A). In FIG. 13A only one first trench 1071 and one second trench 1072 are illustrated. It should be noted that a plurality of first trenches 1071 and a plurality of second trenches 1072 are formed, wherein the first and second trenches 1071, 1072 are arranged alternatingly in the first lateral direction x1.

Referring to FIG. 13B, the method further includes implanting second (conductivity) type dopant atoms into opposite sidewalls of the first trenches 1071 in a tilted implantation process to form second implanted regions 122′ along the sidewalls. The method further includes covering an upper surface of the epitaxial layer 1240 and sidewalls and bottoms of the second trenches 1072 by a first protection layer 1081 in order to prevent second type dopant atoms from being implanted into sidewalls and bottoms of the second trenches 1072. Referring to FIG. 13C, the method further includes implanting first (conductivity) type dopant atoms into opposite sidewalls of the second trenches 1072 in a tilted implantation process to form first implanted regions 121′ along the sidewalls. The method further includes covering an upper surface of the epitaxial layers 1240 and sidewalls and bottoms of the first trenches 1071 by a second protection layer 1082 in order to prevent second type dopant atoms from being implanted into sidewalls and bottoms of the first trenches 1071.

Referring to FIG. 13D, the method further includes at least partially filling the first and second trenches 1071, 1072 with a monocrystalline semiconductor material. According to one example, the monocrystalline semiconductor material is of the same type as the remainder of the semiconductor body 102. At least partially filling the first and second trenches 1071, 1072 may include an epitaxial growth process.

Referring to FIG. 13E the method further includes forming the first and second trenches 1061, 1062 that define the mesa regions 103 such that second implanted regions 122′ extend along opposite sidewalls of the first trenches 1061 and first implanted regions 121′ extend along opposite sidewalls of the second trenches 1062. The first and second trenches 1061, 1062 may be formed by the same etching process.

Referring to FIG. 13E, the method further includes implanting first type dopant atoms into opposite sidewalls of the first and second trenches 1061, 1062 and implanting second type dopant atoms into opposite sidewalls and bottoms of the first and second trenches 1061, 1062. The method further includes an annealing process in order to activate the implanted dopant atoms. After the annealing process, the first implanted regions 121′ form the first SJ regions 121, the second implanted regions 122 form the second SJ regions 122, the first type dopant atoms implanted into the sidewalls of the first and second trenches 1061, 1062 form the mesa channel regions 104, and the second type dopant atoms implanted into the sidewalls and the bottoms of the first and second trenches 1061, 1062 form the first and second control regions 1101, 1102.

Referring to FIG. 13F, the trench JFET is finished by forming the source regions 124, the source electrodes 1131 in the first trenches 1061, the gate electrodes 1132 in the second trenches 1062, and forming the source metallization 1091 insulated from the gate electrodes 1132 by the insulating layer 126.

In the trench JFET according to FIG. 13F, the semiconductor region 123 separating the first and second SJ regions 121, 122 of each pair has the basic doping concentration of the monocrystalline semiconductor layer formed in the first and second trenches 1071, 1072. Furthermore, the semiconductor region 124 arranged between neighboring first and second SJ regions 121, 122 has the basic doping concentration of the epitaxial layer 1240 formed on top of the region 119′.

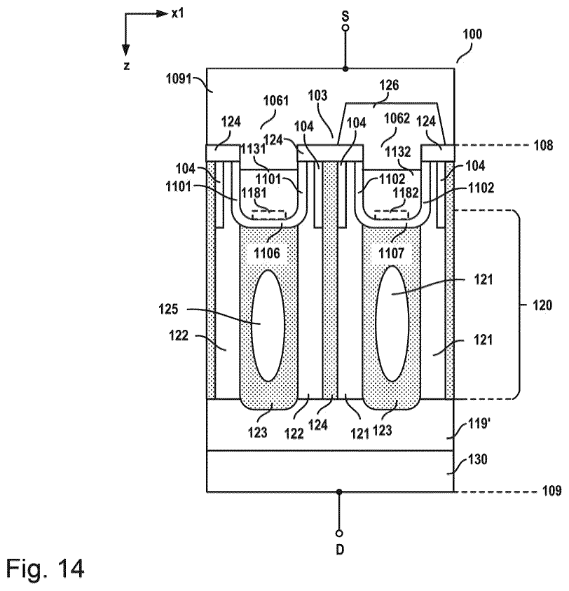

Referring to the above, the first and second trenches 1071, 1072 into which the dopant atoms for forming the first and second SJ regions 121, 122 are implanted, are at least partially filled. FIG. 14 shows a modification of the trench JFET according to FIG. 13F. The trench JFET according to FIG. 14 is different from the trench JFET according to FIG. 13F in that the first and second trenches 1071, 1072 are only partially filled, so that a respective void 125 remains below each of the first and second trenches 1061, 1062 and between the first and second SJ regions 121, 122 of each pair.

Some of the aspects explained above are briefly summarized in the following with reference to numbered examples.

Example A1. A trench junction field effect transistor, JFET,, including: a mesa region confined by first and second trenches spaced apart from each other in a first lateral direction of a semiconductor body, the first and second trenches extending from a first surface into the semiconductor body; a mesa channel region of a first conductivity type; a first control region of a second conductivity type complementary to the first conductivity type arranged in the mesa region adjacent to the first trench; and a second control region of the second conductivity type arranged in the mesa region adjacent to the second trench, wherein the mesa channel region is arranged, in the first lateral direction, between the first control region and the second control region, and wherein the first control region is electrically coupled to a source contact, and the second control region is electrically coupled to a gate contact.

Example A2. The trench JFET of example A1, wherein a first pn junction is arranged between the mesa channel region and the first control region, and wherein a second pn junction is arranged between the mesa channel region and the second control region.

Example A3. The trench JFET of example A1, wherein the mesa channel region is spaced apart from the first control region in the first lateral direction, and/or wherein the mesa channel region is spaced apart from the second control region in the first lateral direction.

Example A4. The trench JFET of example A3, wherein a semiconductor region having a lower doping concentration than each of the mesa channel region and the first control region is arranged between the mesa channel region and the first control region, and/or wherein a semiconductor region having a lower doping concentration than each of the mesa channel region and the second control region is arranged between the mesa channel region and the second control region.

Example A5. The trench JFET of any one of examples A1 to A4, wherein the mesa channel region includes a first mesa channel region and a second mesa channel region spaced apart from each other in the first lateral direction, wherein the first mesa channel region is arranged adjacent to the first control region, and wherein the second mesa channel region is arranged adjacent to the second control region.

Example A6. The trench JFET of any one of the preceding claims, wherein the first trench includes a dielectric trench filling structure.

Example A7. A trench junction field effect transistor, trench JFET, including: a mesa region confined by first and second trenches along a first lateral direction, the first and second trenches extending into a semiconductor body from a first surface of the semiconductor body; a mesa channel region of a first conductivity type; a first control region of a second conductivity type complementary to the first conductivity type arranged in the mesa region adjacent to the first trench; and a second control region of the second conductivity type arranged in the mesa region adjacent to the second trench, wherein the mesa channel region is arranged, in the first lateral direction, between the first control region and the second control region, and wherein each of the first and second trenches includes a gate or source electrode and a bottom electrode, the gate or source electrode being arranged between the bottom electrode and the first surface.

Example A8. The trench JFET of example A7, further including a dielectric separation region arranged between the bottom electrode and the gate electrode.

Example A9. The trench JFET of example A7 or A8, wherein each of the first and second control regions is divided into a top part and a bottom part, wherein the top part and the bottom part are vertically spaced from one another by an intermediate separation region of the first conductivity type.

Example A10. The trench JFET of example A9, wherein the intermediate separation region adjoins to the dielectric separation region along the first lateral direction.

Example A11. The trench JFET of any one of examples A1 to A10, further including a first conductive liner at a sidewall portion of at least one of the first and second trenches, the first conductive liner being laterally arranged between a trench filling material in the at least one of the first and second trenches and a corresponding one of the first and second control regions.

Example A12. The trench JFET of any one of examples A1 to A11, further including a second conductive liner at a bottom portion of at least one of the first and second trenches, the second conductive liner being vertically arranged between a trench filling material in the at least one of the first and second trenches and a corresponding one of the first and second control regions.

Example A13. The trench JFET of any of examples A1 to A12, further including a superjunction, SJ, structure arranged between a bottom side of the first and second trenches and a second surface of the semiconductor body opposite to the first surface.

Example A14. The trench JFET of example A13, wherein the superjunction structure includes a first SJ region of the first conductivity type arranged between two second SJ regions of the second conductivity type, wherein the first SJ region is electrically coupled to a drain contact at the second surface of the semiconductor body and to the source contact at the first surface of the semiconductor body, wherein one of the two second SJ regions is electrically coupled to the first control region, and wherein the other one of the two second SJ regions is electrically coupled to the second control region.

Example A15. The trench JFET of example A13, wherein the superjunction structure includes a first SJ region of the first conductivity type and a second SJ region of the second conductivity type arranged next to each other in the first lateral direction, wherein the first SJ region is electrically coupled between the mesa channel region and a drain region of the first conductivity type, wherein the second SJ region is electrically coupled to the first control region and is spaced apart from the second control region.

Example A16. The trench JFET of example A15, wherein the mesa channel region, in a vertical direction of the semiconductor body, is arranged next to a portion of the first SJ region and a portion of the second SJ region.

Example A17. The trench JFET of example A16, wherein the mesa channel region includes a first mesa channel region arranged next to the first control region and a second mesa channel region arranged next to the second control region, wherein the first and second mesa channel regions are spaced apart from each other in the first lateral direction, wherein the first mesa channel region, in the vertical direction is arranged next to a portion of the second SJ region, and wherein the second mesa channel region, in the vertical direction is arranged next to a portion of the first SJ region.

Example A18. The trench JFET of any one of examples A14 to A17, wherein the JFET includes a plurality of first and second trenches arranged alternatingly in the first lateral direction and a plurality of first and second SJ regions arranged alternatingly in the first lateral direction.

Example A19. The trench JFET of example A18, wherein each first SJ region, in the vertical direction, is arranged below a respective second trench, and wherein each second SJ region, in the vertical direction is arranged below a respective first trench.

Example A20. The trench JFET of example A18, wherein two first SJ regions are arranged next to each other, spaced apart from each other in the first lateral direction, and, in the vertical direction are at least partially arranged below a respective second trench, and wherein two second SJ regions are arranged next to each other, spaced apart from each other in the first lateral direction, and, in the vertical direction are at least partially arranged below a respective first trench.

Example A21. The trench JFET of example A19 or A20, wherein a vertical extension of the superjunction structure ranges from 50% to 2000% of a vertical extension of the first and second trenches.

Example A22. The trench JFET of any one of examples A1 to A21, further including a source region of the second conductivity type arranged on the one of opposite sidewalls of the mesa region that adjoins to the second trench.

Example A23. The trench JFET of any of examples A1 to A22, further including a second mesa region, the second mesa region being wider than the mesa region, and wherein the second trench is laterally confined by the mesa region and the second mesa region.

Example A24. The trench JFET of any one of examples A1 to A23, wherein an extent of the mesa region along the first lateral direction ranges from 200 nm to 2 μm.

Example A25. The trench JFET of any one of examples A1 to A24, wherein, along the first lateral direction, the mesa channel region includes, first, second and third mesa channel sub-regions having a same extent along the first lateral direction, and a concentration of dopants of the first conductivity type averaged along the first lateral direction in the second mesa channel sub-region is larger than a concentration of dopants of the first conductivity type averaged along the first lateral direction in each of the first and third mesa channel sub-regions.

Example B1. A trench junction field effect transistor, trench JFET, including: a mesa region confined by first and second trenches along a first lateral direction, the first and second trenches extending into a semiconductor body from a first surface of the semiconductor body; a mesa channel region of a first conductivity type confined, along the first lateral direction, by first and second control regions of a second conductivity type, a first pn junction being defined by the mesa channel region and the first control region, and a second pn junction being defined by the mesa channel region and the second control region, and wherein the first control region is electrically coupled to a source contact, and the second control region is electrically coupled to a gate contact.

Example B2. The trench JFET of example B1, wherein the first trench includes a dielectric trench filling structure.

Example B3. A trench junction field effect transistor, trench JFET, including: a mesa region confined by first and second trenches along a first lateral direction, the first and second trenches extending into a semiconductor body from a first surface of the semiconductor body; a mesa channel region of a first conductivity type confined, along the first lateral direction, by first and second control regions of a second conductivity type, a first pn junction being defined by the mesa channel region and the first control region, and a second pn junction being defined by the mesa channel region and the second control region, and wherein each of the first and second trenches includes a gate or source electrode and a bottom electrode, the gate or source electrode being arranged between the bottom electrode and the first surface.

Example B4. The trench JFET of example B3, further including a dielectric separation region arranged between the bottom electrode and the gate electrode.

Example B5. The trench JFET of any one of examples B1 to B4, wherein each of the first and second control regions is divided into a top part and a bottom part, wherein the top part and the bottom part are vertically spaced from one another by an intermediate separation region of the first conductivity type.

Example B6. The trench JFET of example B5, wherein the intermediate separation region adjoins to the dielectric separation region along the first lateral direction.

Example B7. The trench JFET of any one of examples B1 to B6, further including a first conductive liner at a sidewall portion of at least one of the first and second trenches, the first conductive liner being laterally arranged between a trench filling material in the at least one of the first and second trenches and a corresponding one of the first and second control regions.

Example B8. The trench JFET of any one of examples B1 to B7, further including a second conductive liner at a bottom portion of at least one of the first and second trenches, the second conductive liner being vertically arranged between a trench filling material in the at least one of the first and second trenches and a corresponding one of the first and second control regions.

Example B9. The trench JFET of any one of examples B1 to B8, further including a superjunction structure arranged between a bottom side of the first and second trenches and a second surface of the semiconductor body opposite to the first surface.

Example B10. The trench JFET of example B9, wherein the superjunction structure includes a first SJ region of the first conductivity type, and a second SJ region of the second conductivity type, wherein the first SJ region is electrically coupled to a drain contact at the second surface of the semiconductor body and to the source contact at the first surface of the semi-conductor body, and the second SJ region is electrically coupled to the first and second control regions.

Example B11. The trench JFET of any one of examples B1 to B10, wherein a vertical extension of the superjunction structure ranges from 50% to 2000% of a vertical extension of the first and second trenches.

Example B12. The trench JFET of any one of examples B1 to B11, further including a source region of the second conductivity type arranged on the one of opposite sidewalls of the mesa region that adjoins to the second trench.

Example B13. The trench JFET of any one of examples B1 to B12, further including a second mesa region, the second mesa region being wider than the mesa region, and wherein the second trench is laterally confined by the mesa region and the second mesa region.

Example B14. The trench JFET of any one of examples B1 to B13, wherein an extent of the mesa region along the first lateral direction ranges from 200 nm to 2 μm.

Example B15. The trench JFET of any one of examples B1 to B14, wherein, along the first lateral direction, the mesa channel region includes, first, second and third mesa channel sub-regions having a same extent along the first lateral direction, and a concentration of dopants of the first conductivity type averaged along the first lateral direction in the second mesa channel sub-region is larger than a concentration of dopants of the first conductivity type averaged along the first lateral direction in each of the first and third mesa channel sub-regions.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1-25. (canceled)

26. A trench JFET (junction field effect transistor), comprising:
a mesa region confined by a first trench and a second trench spaced apart from each other in a first lateral direction of a semiconductor body, the first trench and the second trench extending from a first surface into the semiconductor body;
a mesa channel region of a first conductivity type;
a first control region of a second conductivity type complementary to the first conductivity type arranged in the mesa region adjacent to the first trench;
a second control region of the second conductivity type arranged in the mesa region adjacent to the second trench,
wherein the mesa channel region is arranged, in the first lateral direction, between the first control region and the second control region,
wherein the first control region is electrically coupled to a source contact, and
wherein the second control region is electrically coupled to a gate contact.

27. The trench JFET of claim 26,
wherein a first pn junction is arranged between the mesa channel region and the first control region, and
wherein a second pn junction is arranged between the mesa channel region and the second control region.

28. The trench JFET of claim 26,
wherein the mesa channel region is spaced apart from the first control region in the first lateral direction, and/or
wherein the mesa channel region is spaced apart from the second control region in the first lateral direction.

29. The trench JFET of claim 28, further comprising:
a semiconductor region having a lower doping concentration than each of the mesa channel region and the first control region is arranged between the mesa channel region and the first control region, and/or
a semiconductor region having a lower doping concentration than each of the mesa channel region and the second control region is arranged between the mesa channel region and the second control region.

30. The trench JFET of claim 26,
wherein the mesa channel region comprises a first mesa channel region and a second mesa channel region spaced apart from each other in the first lateral direction,
wherein the first mesa channel region is arranged adjacent to the first control region, and
wherein the second mesa channel region is arranged adjacent to the second control region.

31. The trench JFET of claim 26, wherein the first trench comprises a dielectric trench filling structure.

32. A trench JFET (junction field effect transistor), comprising:
a mesa region confined by a first trench and a second trench along a first lateral direction, the first trench and the second trench extending into a semiconductor body from a first surface of the semiconductor body;
a mesa channel region of a first conductivity type;
a first control region of a second conductivity type complementary to the first conductivity type arranged in the mesa region adjacent to the first trench;
a second control region of the second conductivity type arranged in the mesa region adjacent to the second trench,
wherein the mesa channel region is arranged, in the first lateral direction, between the first control region and the second control region, and
wherein each of the first trench and the second trench includes a gate or source electrode and a bottom electrode, the gate or source electrode being arranged between the bottom electrode and the first surface.

33. The trench JFET of claim 32, further comprising:
a dielectric separation region arranged between the bottom electrode and the gate electrode.

34. The trench JFET of claim 32, wherein each of the first control region and the second control region is divided into a top part and a bottom part, and wherein the top part and the bottom part are vertically spaced from one another by an intermediate separation region of the first conductivity type.

35. The trench JFET of claim 34, wherein the intermediate separation region adjoins the dielectric separation region along the first lateral direction.

36. The trench JFET of claim 32, further comprising:
a conductive liner at a sidewall portion of at least one of the first trench and the second trench, the conductive liner being laterally arranged between a trench filling material in the at least one of the first trench and the second trench and a corresponding one of the first control region and the second control region.

37. The trench JFET of claim 32, further comprising:
a conductive liner at a bottom portion of at least one of the first trench and the second trench, the conductive liner being vertically arranged between a trench filling material in the at least one of the first trench and the second trench and a corresponding one of the first control region and the second control region.

38. The trench JFET of claim 32, further comprising:
a superjunction structure arranged between a bottom side of each of the first trench and the second trench and a second surface of the semiconductor body opposite to the first surface.

39. The trench JFET of claim 38,
wherein the superjunction structure includes a first superjunction region of the first conductivity type arranged between two second superjunction regions of the second conductivity type,
wherein the first superjunction region is electrically coupled to a drain contact at the second surface of the semiconductor body and to a source contact at the first surface of the semiconductor body,
wherein one of the two second superjunction regions is electrically coupled to the first control region, and
wherein the other one of the two second superjunction regions is electrically coupled to the second control region.

40. The trench JFET of claim 38,
wherein the superjunction structure comprises a first superjunction region of the first conductivity type and a second superjunction region of the second conductivity type arranged next to each other in the first lateral direction,
wherein the first superjunction region is electrically coupled between the mesa channel region and a drain region of the first conductivity type, and
wherein the second superjunction region is electrically coupled to the first control region and is spaced apart from the second control region.

41. The trench JFET of claim 40,
wherein the mesa channel region, in a vertical direction of the semiconductor body, is arranged next to a portion of the first superjunction region and a portion of the second superjunction region.

42. The trench JFET of claim 41,
wherein the mesa channel region comprises a first mesa channel region arranged next to the first control region and a second mesa channel region arranged next to the second control region,
wherein the first mesa channel region and the second mesa channel region are spaced apart from each other in the first lateral direction,
wherein the first mesa channel region, in the vertical direction, is arranged next to a portion of the second superjunction region, and
wherein the second mesa channel region, in the vertical direction, is arranged next to a portion of the first superjunction region.

43. The trench JFET of claim 38,
wherein the trench JFET comprises a plurality of first and second trenches arranged alternatingly in the first lateral direction and a plurality of first and second superjunction regions arranged alternatingly in the first lateral direction.

44. The trench JFET of claim 43,
wherein each first superjunction region, in the vertical direction, is arranged below a respective second trench, and
wherein each second superjunction region, in the vertical direction, is arranged below a respective first trench.

45. The trench JFET of claim 43,
wherein two first superjunction regions are arranged next to each other, spaced apart from each other in the first lateral direction, and, in the vertical direction, are at least partially arranged below a respective second trench, and
wherein two second superjunction regions are arranged next to each other, spaced apart from each other in the first lateral direction, and, in the vertical direction, are at least partially arranged below a respective first trench.

46. The trench JFET of claim 38, wherein a vertical extension of the superjunction structure ranges from 50% to 2000% of a vertical extension of each of the first trench and the second trench.

47. The trench JFET of claim 32, further comprising:
a source region of the second conductivity type arranged on a sidewall of the mesa region that adjoins the second trench.

48. The trench JFET of claim 32, further comprising:
a second mesa region, the second mesa region being wider than the mesa region,
wherein the second trench is laterally confined by the mesa region and the second mesa region.

49. The trench JFET of claim 32, wherein an extent of the mesa region along the first lateral direction ranges from 200 nm to 2 μm.

50. The trench JFET of claim 32, wherein, along the first lateral direction, the mesa channel region includes a first mesa channel sub-region, a second mesa channel sub-region and a third mesa channel sub-region each having a same extent along the first lateral direction, and wherein a concentration of dopants of the first conductivity type averaged along the first lateral direction in the second mesa channel sub-region is larger than a concentration of dopants of the first conductivity type averaged along the first lateral direction in each of the first mesa channel sub-region and the third mesa channel sub-region.
